(19) United States
(12) Patent Application Publication
(10) Pub. No.: US 2009/0016118 A1
(43) Pub. Date: Jan. 15, 2009

(54) NON-VOLATILE DRAM WITH FLOATING GATE AND METHOD OF OPERATION

(75) Inventors: Yuniarto Widjaja, San Jose, CA (US); Dana Lee, Santa Clara, CA (US)

Correspondence Address: DLA PIPER US LLP, 2000 UNIVERSITY AVENUE, E. PALO ALTO, CA, 94303-2248, US

(73) Assignee: Silicon Storage Technology, Inc.

(21) Appl. No.: 11/777,138

(22) Filed: Jul. 12, 2007

(51) Int. Cl. G11C 16/04; H01L 29/788

(52) U.S. Cl. 365/185.26; 257/316; 257/E29.3

(57) ABSTRACT

A non-volatile capacitor-less 1T DRAM has a semiconductor substrate of a first conducting type with a surface. A first region of a second conductivity type is in the substrate on the surface. A second region of the second conductivity type is in the substrate on the surface, spaced apart from the first region. A body region of the first conductivity type is in the substrate between the first region and the second region. The body region is bound by the surface, one or more insulating regions and the first and second regions. The DRAM further has a floating gate insulated from the surface and is positioned between the first region and the second region. A control gate is capacitively coupled to the floating gate.

### TECHNICAL FIELD

The present invention relates to a non-volatile capacitor-less 1 T DRAM cell, and more particularly, to a DRAM cell having a floating gate to store the state of the DRAM cell in the event of a power shutdown, and to restored the state from the floating gate onto the DRAM cell in the event power up or restoration of power.

### BACKGROUND OF THE INVENTION

Non-volatile capacitor-less 1 T DRAM cells are well known in the art. Referring to FIG. 1 there is shown a cross-sectional view of a DRAM cell 10 of the prior art. The cell 10 comprises a substrate 12 of a first conductivity type, such as P type. The substrate 12 has a surface 14. A first region 16 of a second conductivity type, such as N type, is in the substrate 12 on the surface 14. A second region 18 of the second conductivity type is in the substrate 12 on the surface 14, spaced apart from the first region 16. An insulating layer 20 is in the substrate 12. The insulating layer 20, together with the first and second regions 16 and 18 bound a body region 22 of the substrate 12. Thus, the body region 22 in the substrate 12 is bounded by the surface 14, one or more insulating layers 20 and the first and second regions 16 and 18. Finally, a gate electrode 22 is positioned above the surface 14 and is insulated therefrom and is between the first and second regions 16 and 18.

The DRAM cell 10 operates as follows. To store a bit in the cell 10, the following voltages are applied to the various regions: 0 volts to the first region 16, a positive volt, such as +2.0 volts to the second region 18, a slight negative voltage of −2.0 volts is applied to the gate electrode 22, and either a zero volt or a high negative volt, such as −10 volts is applied to the substrate 12, and in particular to the insulating layer 20. Holes generated at the second region 18 either are evacuated from the body region 22, (if there is zero volts applied to the insulating layer 20) or are attracted to the insulating layer 20, and remain in the body region 22 (if there is a large negative voltage applied to the insulating layer 20). Because the body region 22 is bounded by the PN junction of the first and second regions 16 and 18, and by the insulating layer 20, the holes generated in the body 22 are “trapped” for so long as power is supplied to the integrated device to which the cell 10 is a part thereof. However, once power is removed, and the PN junctions between the body region 22 and the first and second regions 16 and 18 dissipate, then the holes will migrate (leak) from the body region 22, and the cell 10 will no longer store the bit state.

To read the DRAM cell 10, the following voltages are applied. 0 volts to the first region 16, a small positive voltage, such as +0.5 volts to the second region 18, a large negative voltage, such as −10 volts to the insulating layer 20, and a positive voltage, such as +2.5 volts to the gate electrode 22. If there are holes stored in the body region 22, then the current at the second region 18 will be larger than if there are no holes stored in the body region 22.

The problem with the DRAM cell 10 of the prior art is that when power is shutdown, the bit state stored in the body region 22 is lost. Thus, the DRAM cell 10 is not truly non-volatile

### SUMMARY OF THE INVENTION

In the present invention, a non-volatile capacitor-less 1 T DRAM has a semiconductor substrate of a first conducting type with a surface. A first region of a second conductivity type is in the substrate on the surface. A second region of the second conductivity type is in the substrate on the surface, spaced apart from the first region. A body region of the first conductivity type is in the substrate between the first region and the second region. The body region is bound by the surface, one or more insulating regions and the first and second regions. The DRAM further has a floating gate insulated from the surface and is positioned between the first region and the second region. A control gate is capacitively coupled to the floating gate.

### BRIEF DESCRIPTION OF THE DRAWINGS

FIG. 1 is a cross-sectional view of a DRAM cell of the prior art.

FIG. 2 is cross-sectional view of a first embodiment of an improved DRAM cell of the present invention.

FIG. 3 is cross-sectional view of a second embodiment of an improved DRAM cell of the present invention.

FIG. 4 is a flow chart showing the operation of the improved DRAM cell of the present invention of either the first or the second embodiment.

### DETAILED DESCRIPTION OF THE INVENTION

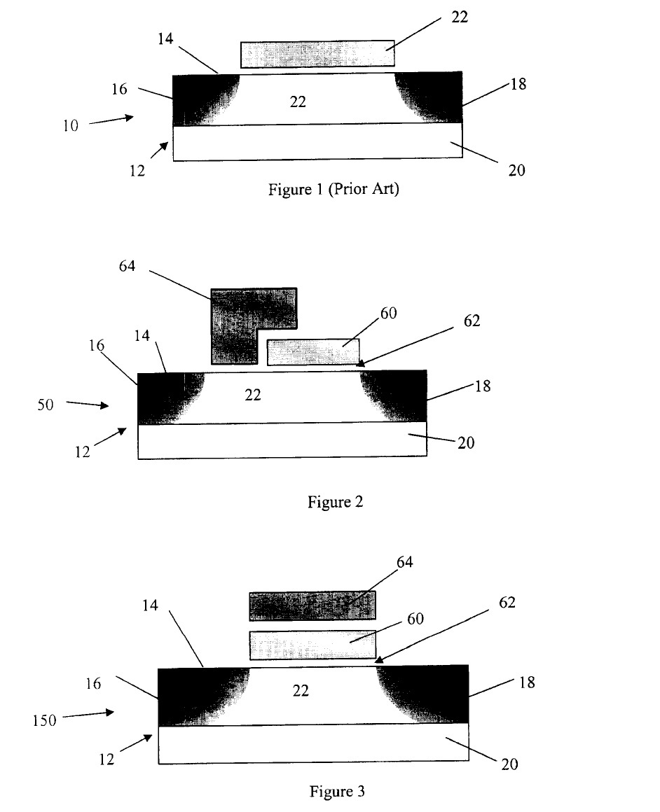

Referring to FIG. 2, there is shown a first embodiment 50 of an improved non-volatile capacitor-less 1 T DRAM cell. The cell 50 has many features similar to the cell 10 of the prior art, and accordingly the same notation will be used. The cell 50 comprises a substrate of a first conductivity type, such as P type. The substrate 12 has a surface 14. A first region 16 of a second conductivity type, such as N type, is in the substrate 12 on the surface 14. A second region 18 of the second conductivity type is in the substrate 12 on the surface 14, spaced apart from the first region 16. An insulating layer 20 is in the substrate 12. The insulating layer 20, together with the first and second regions 16 and 18 bound a body region 22 of the substrate 12. Thus, the body region 22 in the substrate 12 is bounded by the surface 14, one or more insulating layers 20 and the first and second regions 16 and 18. A floating gate 60 is positioned above the surface 14 and is insulated therefrom by an insulating layer 62 and is between the first and second regions 16 and 18. In the first embodiment of the cell 50, the floating gate 60 is positioned over a portion of the region between the first region 16 and the second region 18. A control gate 64, insulated and separated from the surface 14 is positioned adjacent to the floating gate 60 and is over another portion of the surface 14 between the first region 16 and the second region 18. The control gate 64 is capacitively coupled to the floating gate 60. In a preferred embodiment, the floating gate 60 has a tip immediately adjacent to the control gate 64 facilitating the tunneling of electrons from the floating gate 60 through its tip to the control gate 64. In this embodiment, the relationship of the floating gate 60 to the control gate 64 is similar to that of a non-volatile split gate floating gate memory cell.

Referring to FIG. 3, there is shown a second embodiment 150 of an improved non-volatile capacitor-less 1 T DRAM cell. The cell 150 has many features similar to the cell 50 shown in FIG. 2, and accordingly the same notation will be used. The cell 150 comprises a substrate 12 of a first conductivity type, such as P type. The substrate 12 has a surface 14. A first region 16 of a second conductivity type, such as N type, is in the substrate 12 on the surface 14. A second region 18 of the second conductivity type is in the substrate 12 on the surface 14, spaced apart from the first region 16. An insulating layer 20 is in the substrate 12. The insulating layer 20, together with the first and second regions 16 and 18 bound a body region 22 of the substrate 12. Thus, the body region 22 in the substrate 12 is bounded by the surface 14, one or more insulating layers 20 and the first and second regions 16 and 18. A floating gate 60 is positioned above the surface 14 and is insulated therefrom by an insulating layer 62 and is between the first and second regions 16 and 18. In the second embodiment of the cell 150, the floating gate 60 is positioned over the entirety of the region between the first region 16 and the second region 18. A control gate 64 is insulated and separated from the floating gate 60 and is capcitively coupled thereto. In this embodiment, the relationship of the floating gate 60 to the control gate 64 is similar to that of a non-volatile stack gate floating gate memory cell.

For each of the cell 50 or cell 150, the operation of read or write is identical to that of the cell 10 of the prior art. The advantage of the cell 50 or cell 150 of the present invention is that when power down is detected, the data stored in the body region 22 of the cell 50 or cell 150 can be written to the floating gate 60, to preserve that data, once power is turned completely off. Similarly, upon power up, the data stored in the floating gate 60 of the cell 50 or the cell 150 can be transferred into the body region 22.

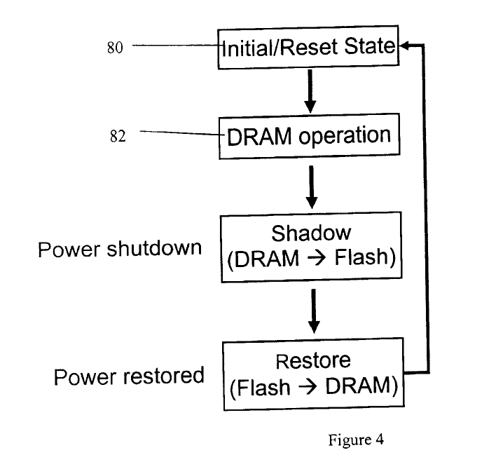

Referring to FIG. 4, there is shown a flow chart of the operation of the cell 50 or the cell 150 of the present invention. Initially, the cell 50 or cell 150 is reset at step 80. For the cell 50 reset is accomplished by applying the following approximate voltages (it should be noted these are merely examples of voltages to be applied, depending upon the scale of the lithography in manufacturing the cell 50 or cell 150): control gate 64 is applied with +12 volts, and the substrate 12 (at the insulating region 20) is applied with −10 volts. When these voltages are applied, electrons on the floating gate 60 are drawn through its tip and are attracted to the control gate 64, leaving the floating gate 60 either neutral or positively charged.

Thereafter, the operation of the cell 50 continues similar to the operation described for the cell 10, when power is applied. The cell 50 operates similar to a conventional 1 T capacitor-less DRAM cell 10. To write a state of “0” into the body region 22, the following voltages are applied: 0.0 volts is applied to the first region 16; +0.5 volts is applied to the second region 18; −2.0 volts is applied to the control gate 64; and 0.0 volts is applied to the insulating layer 20 or the substrate 12. Under these conditions, holes are evacuated from the body region 22, leaving the body region neutrally charged. To write a state of “1” into the body region 22, the following voltages are applied: 0.0 volts is applied to the first region 16; +2.0 volts is applied to the second region 18; −2.0 volts is applied to the control gate 64; and −10.0 volts is applied to the insulating layer 20 or the substrate 12. Under these conditions, holes are injected from the second region 18 into the body region 22, leaving the body region 22 positively charged. To read the cell 50, the following voltages are applied: 0.0 volts is applied to the first region 16; +0.5 volts is applied to the second region 18; +2.5 volts is applied to the control gate 64; and −10.0 volts is applied to the insulating layer 20 or the substrate 12. If the cell 50 is in a state of “0” having holes in the body region 22, then the holes in the body region 22 would cause a greater current than the condition of the cell 50 being in a state of “1” having no holes in the body region 22. The holes causes a faster turn on, similar to a transistor having a lower Vth.

When power down is detected, the data stored in the body region 22 is transferred to the floating gate 60. This occurs in the following manner: control gate is applied with approximately 1.5 volts, the first region 16 is applied with approximately 0 volts; the second region 18 is applied with approximately +7 volts; and the substrate 12 is applied with approximately with −10 volts. Under these conditions, if there are holes in the body region 22, it would allow a programming current to flow between the first region 16 and the second region 18, and the electrons from the first region 16 traversing the channel region between the first region 16 and the second region 18 are injected onto the floating gate 60 rendering it negatively charged. If there are no holes in the body region 22, then no programming current would flow between the first region 16 and the second region 18 and no electrons would be injected onto the floating gate 60, leaving it neutral or positively charged.

When power is restored, and the state of the floating gate 60 must be restored into the body region 22, the following voltages are applied: control gate 64 is applied with approximately −0.5 volts; first region 16 is applied with approximately 0 volts; the second region 18 is applied with approximately with +2.0 volts; and the substrate 12 is applied with approximately −10 volts. If the floating gate 60 is negatively charged, then holes from the second region 18 would be injected into the body region 22 attracted by the negative voltage applied to the insulating layer 20. If the floating gate 60 is neutral or positively charged, then no electrons or holes would be injected into the body region 22, and the body region 22 would remain free of any charges.

For the operation of the cell 150, the voltages applied to the cell 150 for the initialization step 80 is as follows: the control gate 64 is applied with approximately −20 volts; the first and second regions 16 and 18 are left floating; and the insulating layer 20 is applied with approximately −10 volts. Under this condition, electrons from the control gate 64 are injected onto the floating gate 60 rendering it negatively charged.

After the cell 150 is initialized, the cell 150 can operate as a conventional 1 T capacitorless DRAM cell. The voltages applied during the write “0” operation are as follows: 0.0 volts to the first region 16; +0.5 volts to the second region 18; −2.0 volts to the control gate 64; and 0.0 volts to the insulating layer 20. In this case, holes are evacuated from the body region 22. To write the state of “1” the voltages applied are as follows: 0.0 volts to the first region 16; +2.0 volts to the second region 18; −2.0 volts to the control gate 64; and −10.0 volts to the insulating layer 20. In this case, injected into the body region 22 from the second region 18. Finally, to read the cell 150, the following voltages are applied: 0.0 volts to the first region 16; +0.5 volts to the second region 18; +2.5 volts to the control gate 64; and −10.0 volts to the insulating layer 20. If the cell 150 is written into a state of “1”, holes in the body region 22 would increase the current between the first region 16 and the second region 18 more than if the cell 150 were written into a state of “0” where no holes are in the body region 22. The difference in the amount of current can be detected at the second region 18.

When power down is detected, the following voltages are applied: the first region 16 and the second region 18 are left floating; a voltage of +20.0 volts is applied to the control gate 64; a −10.0 volts is applied to the insulating layer 20. If the floating gate 60 were in the initial state of negatively charged, and there are holes in the body region 22, then the floating gate 60 would remain in the same state as the initial state. If the floating gate 60 were in the initial state of negatively charged, and there are no holes in the body region 22, then the electrons on the floating gate 60 would tunnel to the control gate 64 and the floating gate 60 would become positively charged.

When power is restored, the state of the cell as stored on the floating gate 60 is restored into the body region 22. The following voltages are applied: the first region 16 is left floating; a +2.0 volts is applied to the second region 18; a voltage of −0.5 volts is applied to the control gate 64; a −10.0 volts is applied to the insulating layer 20. If the floating gate 60 is negatively charged (a state of “1”), the negative charge on the floating gate 60 will enhance band-to-band tunneling. As a result, this causes hole generation which are then trapped in the body region 22. If the floating gate 60 is positively charged (a state of “0”), then no band-to-band-tunneling occurs, as it is suppressed by the positive voltage on the floating gate 60. The body region 22 remains neutral.

From the foregoing it can be seen that with the present invention, a non-volatile memory cell having all the advantages of a DRAM cell and that of non-volatility is achieved.

1. In a non-volatile capacitor-less 1T DRAM having:
a semiconductor substrate of a first conducting type with a surface;
a first region of a second conductivity type in said substrate on said surface;
a second region of said second conductivity type in said substrate on said surface, spaced apart from said first region;
a body region of said first conductivity type in said substrate between said first region and said second region, said body region bound by said surface, one or more insulating regions and said first and second regions; wherein the improvement comprising:
a floating gate insulated from said surface and positioned between said first region and said second region; and
a control gate capacitively coupled to said floating gate.

2. The DRAM of claim 1 wherein said floating gate is insulated from a first portion of said surface of said body region between said first region and said second region; and
wherein said control gate is positioned adjacent to the floating gate and is insulated from a second portion of said surface of said body region between said first region and said second region, and is capacitively coupled to said floating gate.

3. The DRAM of claim 1 wherein said floating gate is insulated from said surface of said body region and is positioned over the entire surface between said first region and said second region; and
wherein said control gate is insulated from said floating gate and is positioned over said floating gate.

4. The DRAM of claim 2 wherein said floating gate further having a tip near an end adjacent to the control gate.

5. A method of operating a non-volatile capacitor-less 1T DRAM cell having a semiconductor substrate of a first conducting type with a surface; a first region of a second conductivity type in said substrate on said surface; a second region of said second conductivity type in said substrate, spaced apart from said first region; a body region of said first conductivity type in said substrate between said first region and said second region, said body region bound by said surface, one or more insulating regions and said first and second regions; a floating gate insulated from said surface and positioned between said first region and said second region; and a control gate capacitively coupled to said floating gate; wherein said method comprising:
operating said DRAM cell by storing data in said body region; and
storing said data in said body region to said floating gate upon detection of a loss in power.

6. The method of claim 5 further comprising:
restoring the data stored in the floating gate into the body region, upon application of power to said DRAM.

7. The method of claim 5 wherein said floating gate is insulated from a first portion of said surface of said body region between said first region and said second region, and is closer to said second region than to said first region; and wherein said control gate is positioned adjacent to the floating gate and is insulated from a second portion of said surface of said body region between said first region and said second region, and is capacitively coupled to said floating gate, and is closer to said first region than to said second region.

8. The method of claim 7 wherein said storing step comprises
applying a first negative voltage to the body of the substrate;
applying a first voltage to said first region;
applying a second voltage to said second region, said second voltage more positive than said first voltage; and
applying a third voltage to said control gate, said third voltage more positive than said first voltage, wherein said second voltage and third voltage are sufficient to cause electrons to be injected onto the floating gate if holes are stored in the body region.

9. The method of claim 6 wherein said floating gate is insulated from a first portion of said surface of said body region between said first region and said second region, and is closer to said second region than to said first region; and wherein said control gate is positioned adjacent to the floating gate and is insulated from a second portion of said surface of said body region between said first region and said second region, and is capacitively coupled to said floating gate, and is closer to said first region than to said second region.

10. The method of claim 9, wherein said restoring step comprises:
applying a negative voltage to the body;
applying a first voltage to said first region;
applying a second voltage to said second region, said second voltage more positive than said first voltage; and
applying a third voltage to said control gate, wherein said third voltage is a negative voltage.

11. The method of claim 8, further comprising the step of:
initializing said DRAM prior to said operating step, where in said initializing step comprises:
applying a positive voltage to said control gate;
applying a second negative voltage to the body of said substrate.

12. The method of claim 5 wherein said floating gate is insulated from said surface of said body region and is positioned over the entire surface between said first region and said second region; and wherein said control gate is insulated from said floating gate and is positioned over said floating gate.

13. The methods of claim 12 wherein said storing step comprises:
applying a first positive voltage to the control gate; and
applying a first negative voltage to the body of the substrate.

14. The method of claim 6 wherein said floating gate is insulated from said surface of said body region and is positioned over the entire surface between said first region and said second region; and wherein said control gate is insulated from said floating gate and is positioned over said floating gate.

15. The method of claim 14 wherein said restoring step comprises:
applying a second negative voltage said control gate;
applying a third negative voltage to the body of said substrate, wherein said third negative voltage is more negative than said second negative voltage; and
applying a second positive voltage to said second region.

16. The method of claim 13, further comprising the step of:
initializing said DRAM prior to said operating step, said initializing step comprising:
applying a first negative voltage to said control gate;
applying a second negative voltage to the body of said substrate, wherein said first negative voltage is more negative than said second negative voltage.
